(19) United States
(12) Patent Application Publication
(10) Pub. No.: US 2026/0162928 A1
(43) Pub. Date: Jun. 11, 2026

(54) HIGH-VOLTAGE POWER SUPPLY

(71) Applicant: HITACHI HIGH-TECH CORPORATION, Tokyo (JP)

(72) Inventors: Ryo KADOI, Tokyo (JP); Wen LI, Tokyo (JP); Naoya ISHIGAKI, Tokyo (JP)

(21) Appl. No.: 18/722,645

(22) PCT Filed: Jan. 31, 2022
(86) PCT No.: PCT/JP2022/003682

§ 371 Date: Jun. 21, 2024

(51) Int. Cl. H01J 37/24; H05K 9/00

(52) U.S. Cl. CPC H01J 37/241; H05K 9/0083

(57) ABSTRACT

To reduce propagation of spatial noise generated in a high-voltage generation circuit to an output terminal, and reduce a size of a high-voltage power supply. A high-voltage power supply includes: a high-voltage generation circuit; a filter circuit connected to the high-voltage generation circuit; an output resistor connected to the filter circuit via a first connection conductor; an output terminal connected to the output resistor via a second connection conductor; and a spatial noise blocking conductor connected to the first connection conductor, and having at least a portion disposed between the high-voltage generation circuit and the second connection conductor.

### TECHNICAL FIELD

The present invention relates to a high-voltage power supply, and more particularly, to a high-voltage power supply having a spatial noise blocking conductor that blocks spatial noise.

### BACKGROUND ART

As a technique for blocking spatial noise generated in a high-voltage power supply, PTL 1 (paragraph 0004) discloses that “a shield plate S for reducing an influence of transmission noise on a transmitted high voltage is disposed between an acceleration voltage generation circuit 1 and a power transmission circuit 7”.

### CITATION LIST

### Patent Literature

PTL 1: JP2006-156155A

### SUMMARY OF INVENTION

### Technical Problem

In PTL 1, in order to reduce propagation of spatial noise generated in the acceleration voltage generation circuit to an output terminal, a shield plate 6 for reducing the spatial noise is disposed. As shown in FIGS. 1 and 2, the shield plate 6 is connected to GND. In order to use the shield plate 6 connected to the GND in a high-voltage generation device, it is necessary to secure an insulation distance between high voltage portion such as the acceleration voltage generation circuit and the shield plate 6, and thus a size of the high-voltage generation device may become large.

The invention provides a technique capable of reducing propagation of spatial noise generated in a high-voltage generation circuit to an output terminal, and reducing a size of a high-voltage power supply.

### Solution to Problem

In order to solve the above problems, a high-voltage power supply according to the invention includes: a high-voltage generation circuit; a filter circuit connected to the high-voltage generation circuit; an output resistor Connected to the filter circuit via a first connection conductor; an output terminal connected to the output resistor via a second connection conductor; and a spatial noise blocking conductor connected to the first connection conductor and having at least a portion disposed between the high-voltage generation circuit and the second connection conductor.

### Advantageous Effects of Invention

According to the invention, it is possible to reduce propagation of spatial noise generated in a high-voltage generation circuit to an output terminal, and reduce a size of a high-voltage power supply.

Problems, configurations, and effects other than those described above will become apparent by description of the following embodiments.

### BRIEF DESCRIPTION OF DRAWINGS

FIG. 1 is a diagram showing a configuration of a high-voltage power supply according to Embodiment 1.

FIG. 2 is a perspective view of the high-voltage power supply according to Embodiment 1.

FIG. 3 is a perspective view of a high-voltage power supply according to Embodiment 2.

FIG. 4 is a diagram showing a configuration of a high-voltage power supply according to Embodiment 3.

### DESCRIPTION OF EMBODIMENTS

Embodiments according to the disclosure will be described in detail with reference to the drawings. In the following embodiments, it is needless to mention that components thereof are not necessarily essential unless otherwise specified or unless clearly considered to be essential in principle. Hereinafter, preferred embodiments of the present disclosure will be described with reference to the drawings.

### Embodiment 1

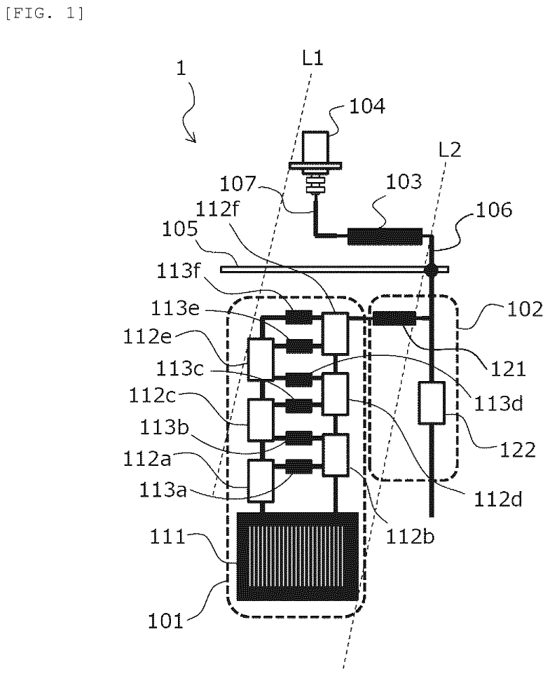

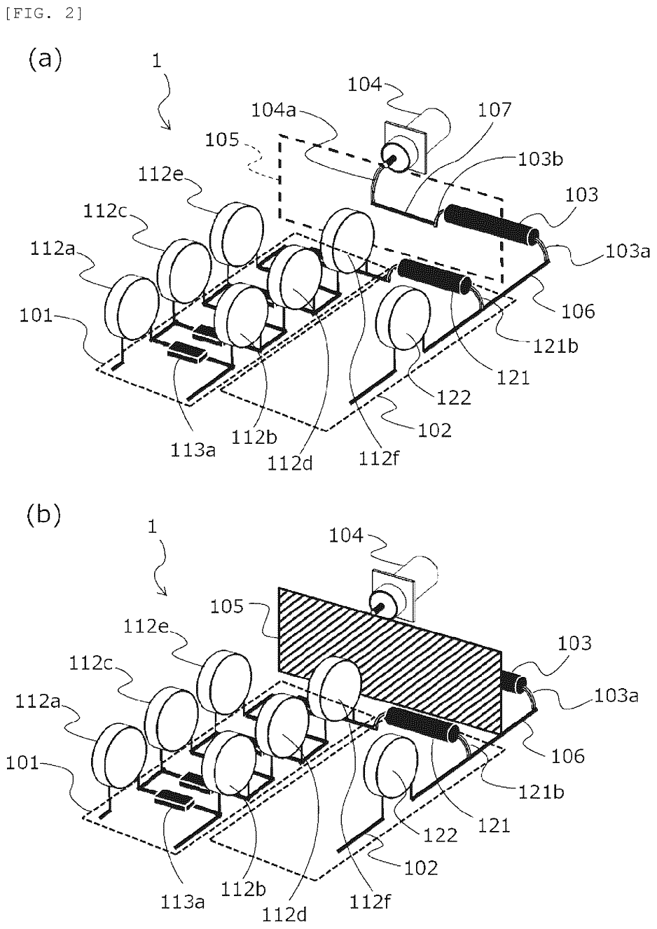

FIG. 1 is a diagram showing a configuration of a high-voltage power supply according to Embodiment 1. FIG. 2 is a perspective view of the high-voltage power supply according to Embodiment 1 shown in FIG. 1. (a) of FIG. 2 is a diagram in which a spatial noise blocking conductor 105 is omitted from (b) of FIG. 2. The high-voltage power supply 1 according to Embodiment 1 is a power supply used in an electron microscope, and can be used as an electron gun power supply used in an electron microscope or a voltage application power supply to a stage structure. The high-voltage power supply 1 according to Embodiment 1 may be used in a device other than the electron microscope. The term “high-voltage” refers to a voltage of, for example, 100 V or more.

As shown in FIG. 1, the high-voltage power supply 1 includes a high-voltage generation circuit 101, a filter circuit 102, an output resistor 103, an output terminal 104, and the spatial noise blocking conductor 105. The high-voltage power supply 1 is an assembly in which the high-voltage generation circuit 101, the filter circuit 102, the output resistor 103, the output terminal 104, and the spatial noise blocking conductor 105 are mounted on one substrate.

The high-voltage generation circuit 101 is, for example, a Cockcroft-Walton circuit. The high-voltage generation circuit 101 includes an AC power supply 111, a plurality Of capacitors 112a to 112f (hereinafter, the plurality of capacitors 112a to 112f are collectively referred to as a capacitor 112 as appropriate), and a plurality of diodes 113a to 113f (hereinafter, the plurality of diodes 113a to 113f are collectively referred to as a diode 113 as appropriate). The capacitor 112 includes the capacitor 112f at the last stage that outputs an output voltage of the high-voltage generation circuit 101, and the capacitors 112a to 112e that output voltages lower than the output voltage. The diode 113 includes the diode 113f at the last stage that outputs the output voltage of the high-voltage generation circuit 101, and the diodes 113a to 113e that output voltages lower than the output voltage. Arrangement positions of the output terminal 104, the output resistor 103, and the spatial noise blocking conductor 105 are closer to the capacitor 112f at the last stage than to the capacitors 112a to 112e and closer to the diode 113f at the last stage than to the diodes 113a to 113e.

The filter circuit 102 is, for example, an RC filter circuit. The filter circuit 102 includes a resistor 121 and a capacitor 122. The filter circuit 102 is electrically connected to the high-voltage generation circuit 101. An output of the high-voltage generation circuit 101 is output to the output resistor 103 via the filter circuit 102.

The output resistor 103 is electrically connected to the filter circuit 102 via a wiring pattern (first connection conductor) 106 formed on the substrate on which the filter circuit 102 and the output resistor 103 are mounted. As shown in FIG. 2, one end of the wiring pattern 106 is connected to an output pin 121b of the resistor 121 of the filter circuit 102, and the other end of the wiring pattern 106 is connected to an input pin 103a of the output resistor 103.

As shown in (a) of FIG. 2, the output terminal 104 is electrically connected to the output resistor 103 via a wiring pattern (second connection conductor) 107 formed on the substrate. One end of the wiring pattern 107 is connected to an output pin 103b of the output resistor 103, and the other end of the wiring pattern 107 is connected to an input pin 104a of the output terminal 104.

The spatial noise blocking conductor 105 is a conductor for blocking spatial noise, and is a plate-shaped metal The spatial noise blocking conductor 105 is electrically connected to the wiring pattern 106. The resistor 121 of the filter circuit 102 connects the wiring pattern 106 to the high-voltage generation circuit 101. Since a voltage drop in the resistor 121 is smaller than the output voltage of the high-voltage generation circuit 101, a voltage of the wiring pattern 106 is substantially equal to the output voltage of the high-voltage generation circuit 101. As shown in FIG. 1, at least a portion of the spatial noise blocking conductor 105 is disposed between the high-voltage generation circuit 101 and the wiring pattern 107. Further, at least a portion of the spatial noise blocking conductor 105 is disposed between the high-voltage generation circuit 101 and the output terminal 104. At least a portion of the spatial noise blocking conductor 105 is disposed between the high-voltage generation circuit 101 and the output resistor 103.

At least a portion of the spatial noise blocking conductor 105 according to Embodiment 1 is disposed on straight lines L1 and L2 passing through any of the output resistor 103, the wiring pattern 107, and the output terminal 104, and the high-voltage generation circuit 101. For example, in the example of FIG. 1, at least a portion of the spatial noise blocking conductor 105 is disposed on the straight line L1 passing through the high-voltage generation circuit 101 (left end of the capacitor 112e) and the output terminal 104 (left end of the output terminal 104). At least a portion o the spatial noise blocking conductor 105 is disposed on the straight line L2 passing through the high-voltage generation circuit 101 (right end of the AC power supply 111) and the output resistor 103 (right end of the output resistor 103).

### Effects of Embodiment 1

The high-voltage generation circuit 101 is a main noise source of the spatial noise. Since the output resistor 103 and the output terminal 104 have high impedance due to a resistance component of the output resistor 103, the output resistor 103 and the output terminal 104 are easily influenced by the spatial noise. The spatial noise blocking conductor 105 according to Embodiment 1 is electrically connected to the wiring pattern 106, and at least a portion of the spatial noise blocking conductor 105 is disposed between the high-voltage generation circuit 101 and the wiring pattern 107. By connecting the spatial noise blocking conductor 105 immediately after the filter circuit 102, it is possible to prevent the spatial noise blocking conductor 105 itself from becoming the noise source. Further, by arranging at least a portion of the spatial noise blocking conductor 105 between the high-voltage generation circuit 101 and the wiring pattern 107, it is possible to reduce propagation of the spatial noise to the output terminal 104 via the wiring pattern 107. Further, the spatial noise blocking conductor 105 is electrically connected to the wiring pattern 106 which is not GND, so that it is not necessary to secure an insulation distance, and thus a size of the high-voltage power supply 1 can be reduced.

The arrangement positions of the output terminal 104, the output resistor 103, and the spatial noise blocking conductor 105 are closer to first elements (capacitor 112f, diode 113f) than to second elements (capacitors 112a to 112e, diodes 113a to 113e). With such a configuration, the insulation distance between the spatial noise blocking conductor 105 and the high-voltage generation circuit 101 becomes shorter, so that the size of the high-voltage power supply 1 can be further reduced.

Since the spatial noise blocking conductor 105 is the conductor for blocking the spatial noise, the spatial noise generated in the high-voltage generation circuit 101 can be effectively blocked.

By mounting the filter circuit 102, the output resistor 103, the output terminal 104, and the spatial noise blocking conductor 105 on one substrate, it is possible to reduce the propagation of the spatial noise and to obtain a high-voltage power supply substrate having a reduced size.

By electrically connecting the spatial noise blocking conductor 105 to the wiring pattern 106 formed on the substrate, it is possible to reduce the propagation of the spatial noise generated in the high-voltage generation circuit 101 to the output terminal 104 without increasing a manufacturing cost or the number of steps, and to reduce the size of the high-voltage power supply 1.

Since the spatial noise blocking conductor 105 is a plate-shaped conductor, the spatial noise can be blocked with a simple configuration.

By arranging at least a portion of the spatial noise blocking conductor 105 on the straight lines L1 and L2, the spatial noise from the high-voltage generation circuit 101 to the output terminal 104, the output resistor 103, and the wiring pattern 107 can be effectively reduced.

In the high-voltage power supply 1 adopting the high-voltage generation circuit 101 including the plurality of capacitors 112a to 112f, the plurality of diodes 113a to 113f, and the AC power supply 111, it is possible to reduce the propagation of the spatial noise generated in the high-voltage generation circuit 101 to the output terminal 104 and to reduce the size of the high-voltage power supply 1.

The spatial noise generated from the high-voltage generation circuit 101 can be blocked from the output pin 103b of the output resistor 103 to the input pin 104a of the output terminal 104 by the spatial noise blocking conductor 105.

Further, by arranging at least a portion of the spatial noise blocking conductor 105 between the high-voltage generation circuit 101 and the output terminal 104, it is possible to reduce the propagation of the spatial noise to the output terminal 104.

Further, by arranging at least portion of the spatial noise blocking conductor 105 between the high-voltage generation circuit 101 and the output resistor 103, it is possible to reduce the propagation of the spatial noise to the output resistor 103.

### Embodiment 2

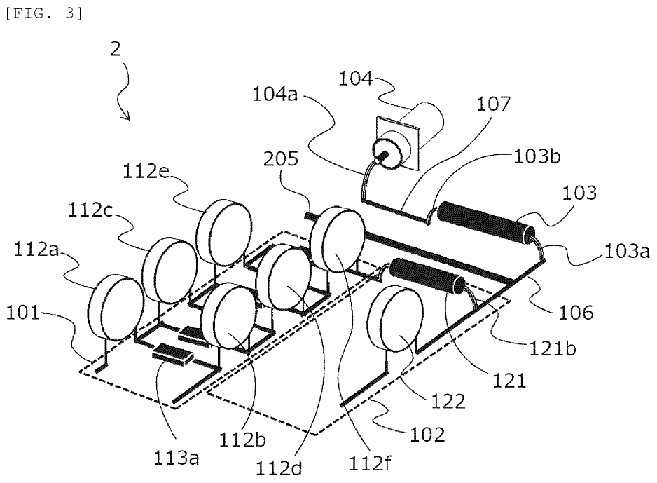

FIG. 3 is a perspective view of a high-voltage power supply according to Embodiment 2. A high-voltage power supply 2 according to Embodiment 2 includes a conductor pattern 205 formed on the substrate instead of the spatial noise blocking conductor 105 according to Embodiment 1. The conductor pattern 205 is the same as the spatial noise blocking conductor 105 according to Embodiment 1 except that the conductor pattern 205 is a wiring pattern formed on the substrate, and redundant description will be omitted.

### Effects of Embodiment 22

The spatial noise can be blocked even when the conductor pattern 205 does not have the plate shape as the spatial noise blocking conductor 105 according to Embodiment 1. In Embodiment 2, the conductor pattern 205 formed on the substrate serves as a spatial noise blocking conductor. Accordingly, it is possible to reduce the propagation of the spatial noise generated in the high-voltage generation circuit 101 to the output terminal 104 without increasing the manufacturing cost or the number of steps, and to reduce the size of the high-voltage power supply 2. Other effects are similar to those of Embodiment 1.

### Embodiment 3

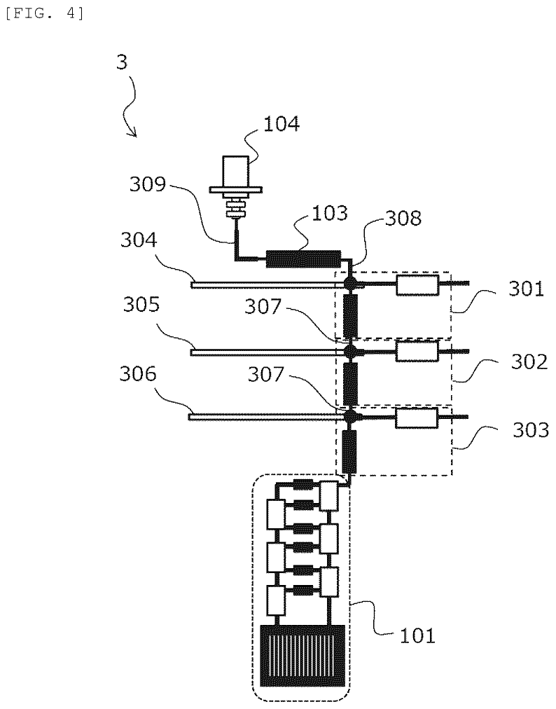

FIG. 4 is a diagram showing a configuration of a high-voltage power supply according to Embodiment 3. A high-voltage power supply 3 according to Embodiment 3 includes a plurality of filter circuits 301, 302, and 303 connected in series, and spatial noise blocking conductors 304, 305, and 306 electrically connected to outputs of the filter circuits 301, 302, and 303, respectively.

As shown in FIG. 4, the high-voltage power supply 3 according to Embodiment 3 includes the high-voltage generation circuit 101, the plurality of filter circuits 301 to 303 connected to the high-voltage generation circuit 101, and a plurality of wiring patterns (connection conductors) 307 connecting the plurality of filter circuits 301 to 303. The high-voltage power supply 3 includes the output resistor 103 connected to the filter circuit 301 at the last stage of the plurality of filter circuits via a wiring pattern (first connection conductor) 308, and the output terminal 104 connected to the output resistor 103 via a wiring pattern (second connection conductor) 309. The high-voltage power supply 3 according to Embodiment 3 includes the spatial noise blocking conductor (first spatial noise blocking conductor) 304 connected to the wiring pattern 308 and having at least a portion disposed between the high-voltage generation circuit 101 and the wiring pattern 309. Further, the high-voltage Supply 3 according to Embodiment 3 includes the spatial noise blocking conductors (second spatial noise blocking conductors) 305 and 306 connected to any one of the plurality of wiring patterns 307 and having at least a portion disposed between the high-voltage generation circuit 101 and the wiring pattern 309.

In Embodiment 3, the case where the number of the filter circuits 301 to 303 and the number of the spatial noise blocking conductors 304 to 306 are both three is described as an example, but the number of the filter circuits and the number of the spatial noise blocking conductors may be two or four or more. The number of filter circuits and the number of spatial noise blocking conductors may not be the same. The spatial noise blocking conductors 304 to 306 may be plate-shaped conductors, wiring patterns formed on a substrate, or a combination of the plate-shaped conductor and the wiring pattern. The conductor patterns 304 to 306 are the same as the spatial noise blocking conductor 105 according to Embodiment 1 except that the plurality of the spatial noise blocking conductors 304 to 306 are provided, and redundant description will be omitted.

### Effects of Embodiment 3

In Embodiment 3, since the spatial noise blocking conductors 304 to 306 are provided for the respective outputs of the filter circuits 301 to 303, the spatial noise generated in the high-voltage generation circuit 101 can be reduced stepwise. As a result, it is possible to further reduce the spatial noise generated in the high-voltage generation circuit 101 as compared with a case where the filter circuit and the spatial noise blocking conductor are provided as one set. Other effects are similar to those of Embodiment 1.

The disclosure is not limited to the above-described embodiments, and includes various modifications. The embodiments described above are described in detail to facilitate understanding of the disclosure, and the disclosure is not necessarily limited to those including all the described configurations. A part of a configuration in one embodiment can be replaced with a configuration in another embodiment, and a configuration in one embodiment can also be added to a configuration in another embodiment. A part of a configuration in each embodiment may also be added to, deleted from, or replaced with another configuration.

### REFERENCE SIGNS LIST

1 high-voltage power supply
2 high-voltage power supply
3 high-voltage power supply
101 high-voltage generation circuit
102 filter circuit
103 output resistor
104 output terminal
105 spatial noise blocking conductor
106 wiring pattern (first connection conductor)
107 wiring pattern (second connection conductor)
205 conductor pattern (spatial noise blocking conductor)
301 to 303 filter circuit
304 spatial noise blocking conductor (first spatial noise blocking conductor)
305, 306 spatial noise blocking conductor (second spatial noise blocking conductor)
307 wiring pattern (connection conductor)
308 wiring pattern (first connection conductor)
309 wiring pattern (second connection conductor)

1. A high-voltage power supply comprising:
a high-voltage generation circuit;

3. filter circuit connected to the high-voltage generation circuit;
an output resistor connected to the filter circuit via a first connection conductor;
an output terminal connected to the output resistor via a second connection conductor; and
a spatial noise blocking conductor connected to the first connection conductor, and having at least a portion disposed between the high-voltage generation circuit and the second connection conductor.

2. The high-voltage power supply according to claim 1, wherein
the high-voltage generation circuit includes a first element configured to output an output voltage of the high-voltage generation circuit and a second element configured to output a voltage lower than the output voltage, and
arrangement positions of the output terminal, the output resistor, and the spatial noise blocking conductor are closer to the first element than to the second element.

3. The high-voltage power supply according to claim 1, wherein
the spatial noise blocking conductor is a conductor for blocking spatial noise.

4. The high-voltage power supply according to claim 1, wherein
the filter circuit, the output resistor, the output terminal, and the spatial noise blocking conductor are mounted on one substrate.

5. The high-voltage power supply according to claim 1, wherein
the first connection conductor is a wiring pattern formed on a substrate on which the filter circuit and the output resistor are mounted, and connecting the output resistor to the filter circuit, and
the spatial noise blocking conductor is connected to the wiring pattern.

6. The high-voltage power supply according to claim 1, wherein
the spatial noise blocking conductor is a plate-shaped conductor.

7. The high-voltage power supply according to claim 1, wherein
the spatial noise blocking conductor is a wiring pattern formed on a substrate on which the filter circuit and the output resistor are mounted.

8. The high-voltage power supply according to claim 1, wherein
at least a portion of the spatial noise blocking conductor is disposed on a straight line passing through any of the output resistor, the second connection conductor, and the output terminal, and the high-voltage generation circuit.

9. The high-voltage power supply according to claim 1, wherein
the high-voltage generation circuit includes a plurality of capacitors, a plurality of diodes, and an AC power supply.

10. The high-voltage power supply according to claim 1, wherein
the second connection conductor is connected to an output pin of the output resistor and an input pin of the output terminal.

11. The high-voltage power supply according to claim 1, wherein
at least a portion of the spatial noise blocking conductor is disposed between the high-voltage generation circuit and the output terminal.

12. The high voltage power supply according to claim 1, wherein
at least a portion of the spatial noise blocking conductor is disposed between the high-voltage generation circuit and the output resistor.

13. A high-voltage power supply comprising:
a high-voltage generation circuit;
a plurality of filter circuits connected in series and connected to the high-voltage generation circuit;
one or a plurality of connection conductors connecting the plurality of filter circuits;
an output resistor connected to a filter circuit at the last stage of the plurality of filter circuits via a first connection conductor;
an output terminal connected to the output resistor via a second connection conductor;
a first spatial noise blocking conductor connected to the first connection conductor and having at least a portion disposed between the high-voltage generation circuit and the second connection conductor; and
a second spatial noise blocking conductor connected to the one or any one of the plurality of connection conductors, and having at least a portion disposed between the high-voltage generation circuit and the second connection conductor.
